(19) United States
(12) Patent Application Publication
(10) Pub. No.: US 2014/0117827 A1
(43) Pub. Date: May 1, 2014

(54) ENCLOSURE WITH POSITIONING STRUCTURE

(71) Applicants: HON HAI PRECISION INDUSTRY CO., LTD., New Taipei (TW); HONG FU JIN PRECISION INDUSTRY (ShenZhen) CO., LTD, Shenzhen (CN)

(72) Inventors: Zhan-Yang LI, Shenzhen (CN); Chong DUAN, Shenzhen (CN)

(21) Appl. No.: 13/921,189

(22) Filed: Jun. 18, 2013

(30) Foreign Application Priority Data
Oct. 29, 2012 (CN) 2012104202361

(51) Int. Cl. H05K 5/02; A47B 88/04

(52) U.S. Cl. CPC H05K 5/0217; A47B 88/04
USPC 312/333

(57) ABSTRACT

An enclosure includes a main body, a securing tray, and a positioning structure. The main body includes a bottom wall and two sidewalls connected to the bottom wall. Each sidewall defines a positioning hole. The securing tray includes a bottom panel. The positioning structure includes two positioning members rotatably attached to the bottom panel and a resilient member located between the two positioning members. Each positioning member includes a positioning portion engaged in the positioning hole. The two positioning members are rotatable about an axis that is substantially perpendicular to the bottom panel, and the resilient member is deformable to disengage the positioning portion from the positioning hole.

### BACKGROUND

1. Technical Field

The present disclosure relates to enclosures, more particularly to an enclosure with a positioning structure.

2. Description of Related Art

Electronic device often comprises an enclosure for receiving a plurality of electronic components. Generally, the enclosure comprises a main body and a supplement securing tray received in the main body. However, the supplement securing tray is secured to the main body by screws, that is time-consuming and laborious. Therefore, there is room for improvement within the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an isometric, cutaway view of an enclosure with a positioning structure in accordance with an embodiment.

FIG. 2 is an assembled view of the enclosure with the positioning structure of FIG. 1.

FIG. 3 is similar to FIG. 2, and a securing tray is out of the enclosure.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean “at least one.”

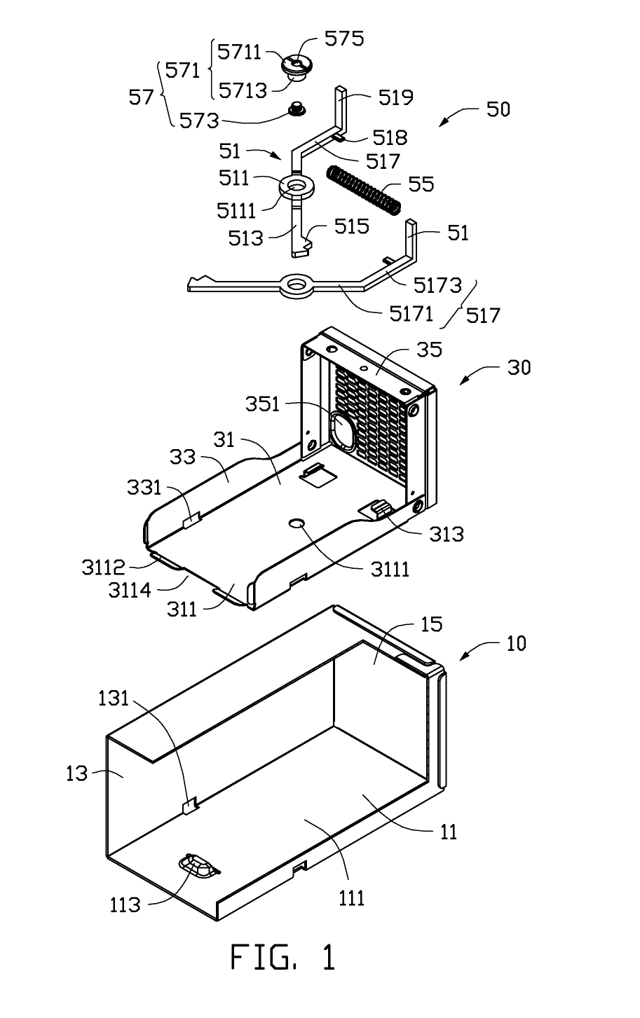

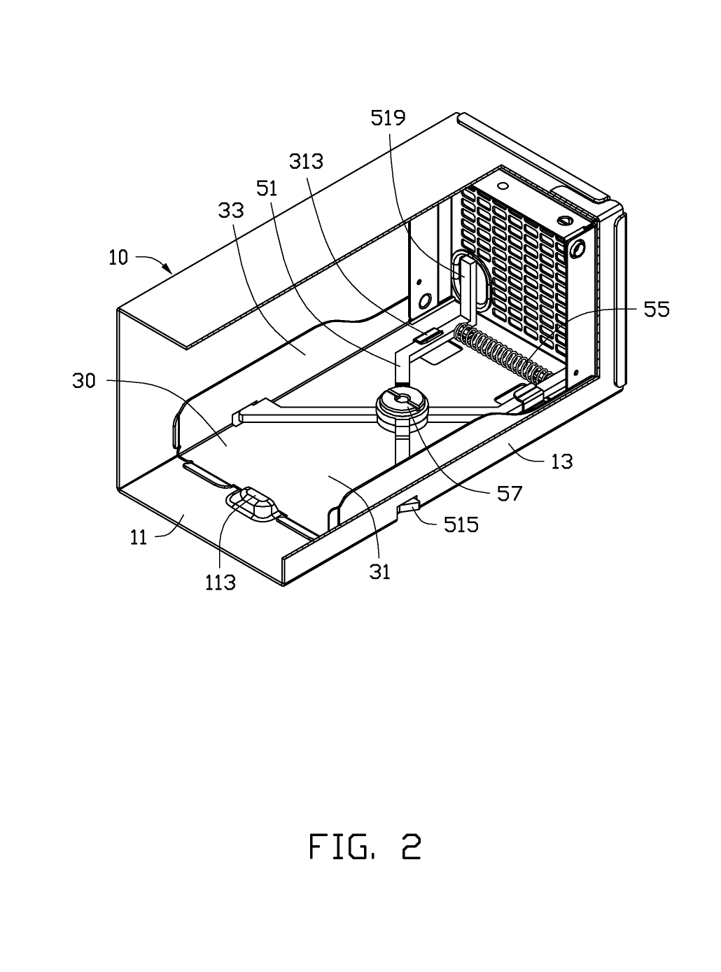

FIGS. 1 and 2 illustrate an enclosure in accordance with an embodiment comprises an main body 10, a securing tray 30, and a positioning structure 50.

The main body 10 comprises a bottom wall 11 and two sidewalls 13 substantially extending from opposite edges of the bottom wall 11. The bottom wall 11 comprises a top surface 111 and a blocking portion 113 protruding from the top surface 111. A positioning hole 131 is located between the bottom wall 11 and each of two sidewalls 13. In one embodiment, the positioning hole 131 is substantially L-shaped. A mounting opening 15 is defined between the two sidewalls 13 and located in the front of the main body 10.

The securing tray 30 comprises a bottom panel 31, a front panel 35 connected to a front edge of the bottom panel 31, and two side panels 33 connected to two side edges of the bottom panel 31. The two side panels 33 are substantially parallel to each other and perpendicular to the bottom panel 31. The bottom panel 31 comprises a bottom panel surface 311 and two limiting pieces 313 extending from the bottom panel surface 311. In one embodiment, each of the two limiting pieces 313 is L-shaped. A securing hole 3111 is defined in the bottom panel surface 311. Two extending pieces 3112 extend from a rear portion of the bottom panel surface 311, and a resisting hole 3114 is defined between the two extending pieces 3112. A through hole 331 is defined in each side panel 33 and corresponds to the positioning hole 131. The front panel 35 is substantially perpendicular to the bottom panel 31. Two operating holes 351 are defined in the front panel 35.

The positioning structure 50 comprises two positioning members 51, a resilient member 55, and a rotating member 57. Each positioning member 51 comprises a rotating portion 511, a first extending arm 513, a second extending arm 514, and a handle 519. A rotating hole 5111 is defined in the rotating portion 511. The first extending arm 513 and the second extending arm 514 extend from opposite sides of the rotating portion 511. A positioning portion 515 extends from a side edge of the first extending arm 513. In one embodiment, the rotating portion 511 is substantially circle, and the positioning portion 515 is substantially triangular.

The second extending arm 517 comprises a first connecting portion 5171 and a second connecting portion 5173. The first connecting portion 5171 is connected to the rotating portion 511, and the second connecting portion 5173 is connected to the rotating portion 511 and the handle 519. In one embodiment, an obtuse angle is defined between the first connecting portion 5171 and the second connecting portion 5173, and the second connecting portion 5173 is substantially perpendicular to the handle 519. A retaining piece 518 extends from a side edge of the second connecting portion 5173 and substantially parallel to the bottom panel 31.

The rotating member 57 comprises an engaging portion 571 and a fixing portion 573. The engaging portion 571 comprises a head 5711 and a neck 5713 extending from the head 5711. A mounting hole 575 is defined in the engaging portion 571 and extends through the head 5711 and the neck 5713.

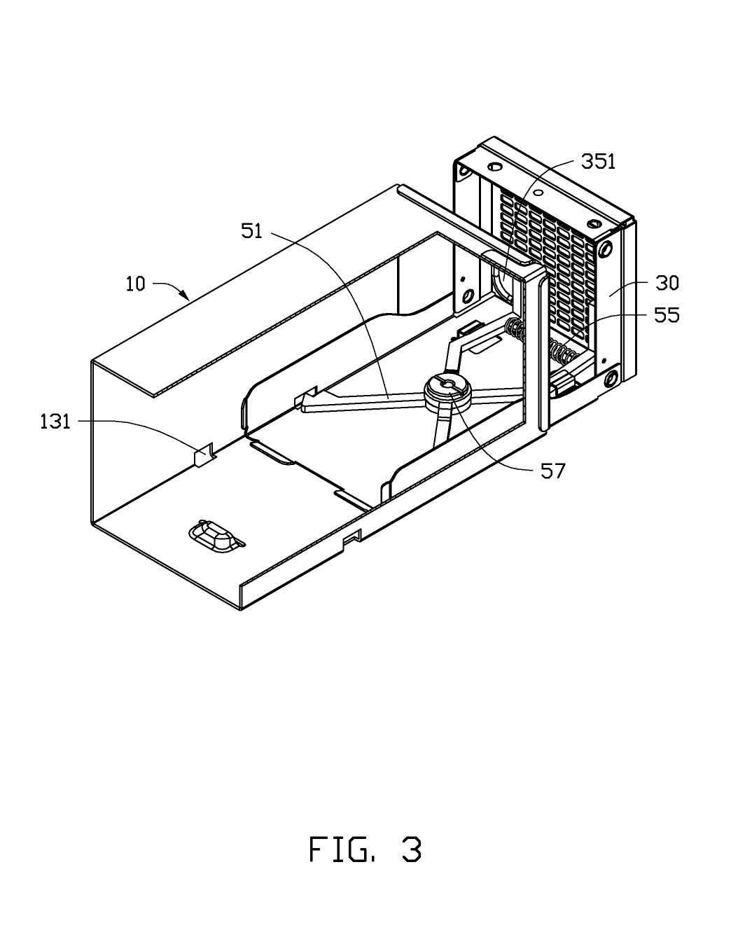

FIGS. 1-3, show in assembly, two ends of the resilient member 55 are engaged with the two retaining pieces 518. The two positioning members 51 are located between the two limiting pieces 313. The securing hole 3111 is aligned with the two rotating holes 5111 of the two positioning members 51. The neck 5713 is received in the two rotating holes 5111. The fixing portion 573 is located below a bottom surface of the bottom panel 31, extending through the bottom panel 31, and engaging in the securing hole 3111. The two rotating holes 5111 extend through the bottom panel surface 311. Thus, the two positioning members 51 are rotatably secured to the bottom panel 31. The two positioning portions 515 are engaged in the two through holes 3111.

The securing tray 30 is pushed into the main body 10 via the mounting opening 15 in a first direction that is substantially parallel to the bottom wall 11. The two positioning portions 515 abut the two sidewalls 13, and the resilient member 55 is deformed. The securing tray 30 is further moved in the first direction, until the two positioning portions 515 are aligned with the two positioning holes 131. The resilient member 55 is released to engage the two positioning portions 515 into the two positioning holes 131. The blocking portion 113 is engaged in the resisting hole 3114 and abuts a free edge of the bottom panel surface 311, for preventing the securing tray 30 from moving in the first direction. The two handles 519 are aligned with the two operating holes 351.

In disassembly, the two handles 519 are moved in opposite directions via the two operating holes 351. The two positioning members 51 are rotated about the rotating member 57. The resilient member 55 is deformed, and the two positioning portions 515 are detached from the two positioning holes 131. The securing tray 30 is moved in a second direction opposite to the first direction, and out of the main body 10 via the mounting opening 15. Therefore, the securing tray 30 is disengaged from the main body 10.

It is to be understood, however, that even though numerous characteristics and advantages have been set forth in the foregoing description of embodiments, together with details of the structures and functions of the embodiments, the disclosure is illustrative only and changes may be made in detail, especially in the matters of shape, size, and arrangement of parts within the principles of the disclosure to the full extent indicated by the broad general meaning of the terms in which the appended claims are expressed.

What is claimed is:

1. An enclosure comprising:
a main body comprising a bottom wall and a first sidewall, connected to the bottom wall; and a first positioning hole defined in the first sidewall;
a securing tray comprising a bottom panel attached to the bottom wall; and
a positioning structure comprising a first positioning member and a resilient member ,abutting the first positioning member; and the first positioning member rotatably attached to the bottom panel and comprising a first positioning portion engaged in the first positioning hole;
wherein the securing tray is slidable relative to the main body in a first direction, that is substantially parallel to the bottom wall; the first positioning member is rotatable about an axis that is substantially perpendicular to the bottom panel; and the resilient member is deformable to disengage the first positioning portion from the first positioning hole.

2. The enclosure of claim 1, wherein the first positioning member further comprises a first rotating portion, a first extending arm, and a second extending arm; the first extending arm and the second extending arm extend from opposite sides of the first rotating portion; the first positioning portion extends from the first extending arm; and a handle extends from the second extending arm.

3. The enclosure of claim 2, wherein the second extending arm comprises a first connecting portion, connected to the first rotating portion, and a second connecting portion, connected to the first connecting portion; and the hand is substantially perpendicular to the second connecting portion.

4. The enclosure of claim 3, wherein the second connecting portion comprises a retaining piece, and the resilient member is engaged with the retaining piece.

5. The enclosure of claim 2, wherein the first rotating portion comprises a first rotating hole, a securing hole is defined in the bottom panel, the positioning structure further comprises a rotating member, and the rotating member extends through the securing hole and the first rotating hole, to rotatably secure the first positioning member to the bottom panel.

6. The enclosure of claim 5, wherein the rotating member comprises an engaging portion and a fixing portion, the engaging portion comprises a head attached to a bottom panel surface of the bottom panel and a neck extending through the first rotating hole and the securing hole, a mounting hole is defined in the rotating member, and the fixing portion extends through the securing hole to engage in the mounting hole.

7. The enclosure of claim 2, wherein the positioning structure further comprises a second positioning member, the second positioning member comprises a second positioning portion, the enclosure comprises a second sidewall opposite to the first sidewall, a second positioning hole defined in the second sidewall, the second positioning portion is engaged in the second positioning hole, and the resilient member is located between the first positioning member and the second positioning member.

8. The enclosure of claim 7 wherein the second positioning member is rotatably engaged with the first positioning member.

9. The enclosure of claim 7, wherein the bottom panel comprises two limiting pieces, and the first positioning member and the second positioning member are located between the two limiting pieces.

10. The enclosure of claim 1, wherein the bottom wall comprises a blocking portion, the blocking abuts the bottom panel, for preventing the securing tray from moving in the first direction.

11. An enclosure comprising:
a main body comprising a bottom wall and two sidewalls, connected to the bottom wall; and a positioning hole defined in each sidewall;
a securing tray comprising a bottom panel attached to the bottom wall; and
a positioning structure comprising two positioning members and a resilient member located between the two positioning members; and the two positioning members rotatably attached to the bottom panel; each positioning member comprising a positioning portion engaged in the positioning hole;
wherein the securing tray is slidable relative to the main body in a first direction, that is substantially parallel to the bottom wall; the two positioning members are rotatable about an axis that is substantially perpendicular to the bottom panel; and the resilient member is deformable to disengage the positioning portion from the positioning hole.

12. The enclosure of claim 11, wherein each positioning member further comprises a rotating portion, a first extending arm, and a second extending arm; the first extending arm and the second extending arm extend from opposite sides of the rotating portion; the positioning portion extends from the first extending arm; and a handle extends from the second extending arm.

13. The enclosure of claim 12, wherein the securing tray further comprises a front panel connected to the bottom panel, an operating hole is defined in the front panel, and the handle is aligned with the operating hole.

14. The enclosure of claim 13, wherein the resilient member is substantially parallel to the front panel.

15. The enclosure of claim 12, wherein the second extending arm comprises a first connecting portion connected to the rotating portion and a second connecting portion connected to the first connecting portion, the hand is substantially perpendicular to the second connecting portion.

16. The enclosure of claim 15, wherein the second connecting portion comprises a retaining piece, and the resilient member is engaged with the retaining piece.

17. The enclosure of claim 12, wherein the rotating portion comprises a rotating hole, a securing hole is defined in the bottom panel, the positioning structure further comprises a rotating member, and the rotating member extends through the securing hole and the rotating hole, to rotatably secure the two positioning members to the bottom panel.

18. The enclosure of claim 17, wherein the rotating member comprises an engaging portion and a fixing portion, the engaging portion comprises a head attached to a bottom panel surface of the bottom panel and a neck extending through the rotating hole and the securing hole, a mounting hole is defined in the rotating member, and the fixing portion extends through the securing hole to engage in the mounting hole.

19. The enclosure of claim 11, wherein the bottom panel comprises two limiting pieces, and the two positioning members are located between the two limiting pieces.

20. The enclosure of claim 11, wherein the securing tray further comprises a side panel connected to the bottom panel, a through hole is defined in the side panel, and the positioning portion extends through the through hole to engage in the positioning hole.
